(19) United States
(12) Patent Application Publication
(10) Pub. No.: US 2013/0002964 A1
(43) Pub. Date: Jan. 3, 2013

(54) TELEVISION RECEIVER AND ELECTRONIC DEVICE

(76) Inventor: Hiroki Kodaira, Tokyo (JP)

(21) Appl. No.: 13/407,458

(22) Filed: Feb. 28, 2012

(30) Foreign Application Priority Data
Jun. 30, 2011 (JP) 2011-146688

(51) Int. Cl. H04N 5/50; H05K 5/00

(52) U.S. Cl. 348/731; 361/807; 348/E05.097

(57) ABSTRACT

According to one embodiment, a television receiver includes: a tuner; a display device; an input module; a housing; a component; a sensor; and an actuator. The input module receives input. The housing includes an opening, and houses the display device and the tuner. The component is removably housed in the opening with at least a portion thereof being exposed to outside of the housing. The sensor outputs a signal based on external force applied to the housing. The actuator restrains the component from coming out from the opening, in response to an output of the signal from the sensor.

### CROSS-REFERENCE TO RELATED APPLICATIONS

This application is based upon and claims the benefit of priority from Japanese Patent Application No. 2011-146688, filed Jun. 30, 2011, the entire contents of which are incorporated herein by reference.

### FIELD

Embodiments described herein relate generally to a television receiver and an electronic device.

### BACKGROUND

Conventionally, widely known are electronic devices that house a pen serving as a component for operating a touch panel in a removable manner in an opening provided to a housing.

It is desired that the pen does not come out of the opening in such an electronic device.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary front view of a television receiver according to a first embodiment;

FIG. 2 is an exemplary front view (partial sectional view) of an opening, a component, and an actuator of the television receiver, and illustrating a state in which a portion of the component protrudes from the opening, in the first embodiment;

FIG. 3 is another exemplary front view (partial sectional view) of the opening, the component, and the actuator of the television receiver, and illustrating a state in which the component is housed in the opening, in the first embodiment;

FIG. 4 is an exemplary front view of a portion of a pushing device provided to the television receiver, and illustrating a state in which a movable portion is retained by a retaining module, in the first embodiment;

FIG. 5 is another exemplary front view of a portion of the pushing device provided to the television receiver, and illustrating a state in which the movable portion is released from the retaining module, in the first embodiment;

FIG. 6 is an exemplary block diagram of a circuit configuration of a control circuit provided to the television receiver in the first embodiment;

FIG. 7 is an exemplary front view (partial sectional view) of an opening, a component, and an actuator of a television receiver, and illustrating a state in which apart of the component protrudes from the opening, according to a second embodiment;

FIG. 8 is another exemplary front view (partial sectional view) of the opening, the component, and the actuator of the television receiver, and illustrating a state in which the component is pushed toward inside of the opening beyond the position illustrated in FIG. 7, in the second embodiment;

FIG. 9 is still another exemplary front view (partial sectional view) of the opening, the component, and the actuator of the television receiver, and illustrating a state in which the component is housed in the opening, in the second embodiment;

FIG. 10 is yet another exemplary front view (partial sectional view) of the opening, the component, and the actuator of the television receiver, and illustrating a state in which the component restrained from moving by the actuator is released, in the second embodiment;

FIG. 11 is an exemplary front view of a television receiver in a first position according a third embodiment;

FIG. 12 is another exemplary front view of the television receiver in a second position in the third embodiment;

FIG. 13 is an exemplary perspective view of an electronic device according to a fourth embodiment;

FIG. 14 is an exemplary block diagram of a circuit configuration of a control circuit provided to the electronic device in the fourth embodiment;

FIG. 15 is an exemplary perspective view of an electronic device according to a fifth embodiment;

FIG. 16 is an exemplary front view of an electronic device according to a sixth embodiment; and

FIG. 17 is another exemplary front view of the electronic device in a different used position from that in FIG. 16, in the sixth embodiment.

### DETAILED DESCRIPTION

In general, according to one embodiment, a television receiver comprises: a tuner; a display device; an input module; a housing; a component; a sensor; and an actuator. The input module is configured to receive input. The housing comprises an opening, and is configured to house the display device and the tuner. The component is configured to be removably housed in the opening with at least a portion thereof being exposed to outside of the housing. The sensor is configured to output a signal based on external force applied to the housing. The actuator is configured to restrain the component from coming out from the opening, in response to an output of the signal from the sensor.

Exemplary embodiments described below comprise components similar to each other. Therefore, in the description below, common numerals are assigned to similar components, and overlapping explanation thereof will be omitted. Furthermore, in the embodiments below, explanations will be made of the case where an electronic device is configured as a television receiver or a personal computer. However, the electronic device according to the embodiments is not limited thereto, and can be configured as various types of electronic devices, such as a smartphone, a smartbook, a mobile phone, a personal digital assistant (PDA), an image display, and a video phone.

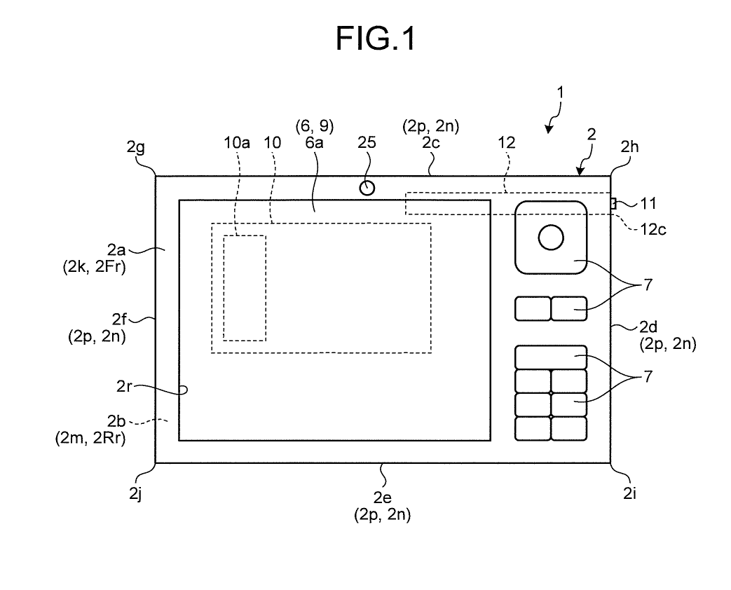

A television receiver 1 serving as an example of the electronic device according to a first embodiment is configured as a portable television. As illustrated in FIG. 1, a housing 2 is configured in a rectangular shape (an oblong shape in the present embodiment, for example) viewed from the front. Furthermore, the housing 2 is configured in a flat rectangular parallelepiped shape that has a small width in the front-back direction. The housing 2 comprises a front surface (a front face, a surface, a first surface, or a first surface portion) 2a, and a rear surface (a back surface, a surface, a second surface, or a second surface portion) 2b opposite thereto. The front surface 2a and the rear surface 2b are approximately parallel to each other. Furthermore, as illustrated in FIG. 1, the housing 2 comprises four ends (sides or edges) 2c to 2f and four corners (peaks, curves, or ends) 2g to 2j viewed from the front. The ends 2c and 2e are examples of a long side, and the ends 2d and 2f are examples of a short side.

The housing 2 further comprises a wall (a first wall, a first section, a plate, a frame, a front wall, a face wall, or a top wall) 2k comprising the front surface 2a and a wall (a second wall, a second section, a plate, a rear wall, a back wall, or a bottom wall) 2m comprising the rear surface 2b. The walls 2k and 2m are in a rectangular shape (an oblong shape in the present embodiment, for example). Furthermore, the housing 2 comprises four walls (third walls, third sections, plates, side walls, end walls, standing walls, or extending portions) 2n comprising a side surface (a surface, a surrounding surface, or a third surface) 2p extending between the wall 2k and the wall 2m. The wall 2k comprises an opening 2r in a rectangular shape, for example.

Furthermore, the housing 2 can be configured by combining a plurality of components (divided parts or members). The housing 2, for example, comprises: a first member (a first section, a front side member, or a cover) 2Fr containing at least the wall 2k; and a second member (a second section, a rear side member, a base, or a bottom) 2Rr containing at least the wall 2m. The wall 2n can be contained in at least one of the first member 2Fr and the second member 2Rr (e.g., the second member 2Rr). The housing 2 can comprise a third member (a third section, a middle member, a dividing member, a barrier member, a wall member, an intervening member, an inner plate, a middle plate, or a middle frame, which is not illustrated) arranged between the first member 2Fr and the second member 2Rr in addition to the first member 2Fr and the second member 2Rr. In this case, the wall 2n can be contained in the third member. The housing 2 can be made of a metal material, a synthetic resin material, and the like.

The housing 2 houses a display device (a display module, a display, or a panel) 6. A display screen 6a arranged on the front surface 2a side of the display device 6 is exposed forward (outside) of the housing 2 through the opening 2r. A user can visually confirm the display screen 6a from the front side through the opening 2r. The display device 6 is configured in a rectangular shape (an oblong shape in the present embodiment, for example) viewed from the front. Furthermore, the display device 6 is configured in a flat rectangular parallelepiped shape that has a small width in the front-back direction. The display device 6 is, for example, a liquid crystal display (LCD) and an organic electro-luminescent display (GELD).

The front side (face side or wall 2k side) of the display device 6 is provided with a transparent input operation panel (e.g., a touch panel, a touch sensor, or an operation surface) 9 in a relatively thin rectangular shape. The input operation panel 9 covers the display screen 6a. An operator (user or the like) uses a finger or a stylus, for example, to perform an operation such as touching, pressing, sliding, or moving in the vicinity of the input operation panel 9 with respect to the input operation panel 9, thereby performing input processing. Furthermore, light output from the display screen 6a of the display device 6 passes through the input operation panel 9, and travels forward (outside) of the housing 2 through the opening 2r of the wall 2k. The input operation panel 9 is an example of an input module.

A plurality of operation buttons 7 are arranged on the front surface 2a of the housing 2. The user operates the operation buttons 7, the input operation panel 9, and the like, thereby performing various types of input operations, such as tuning, volume control, and input of data. In the present embodiment, the operation buttons 7 and the input operation panel 9 correspond to an input operation module. Furthermore, a camera (a camera module, an imaging module, or an imaging device) 25 is provided to the front surface 2a of the housing 2.

The housing 2 houses a board 10 on the rear side (back side, other side, wall 2m side, or side opposite to the display screen 6a) of the display device 6. The board 10 is arranged in a manner parallel to the display device 6.

A plurality of electronic components (components or elements, which are not illustrated), such as a central processing unit (CPU), are mounted on the board (first board, first circuit board, control board, or main board) 10 illustrated in FIG. 1. The electronic components comprise a heating element. An electronic component (heating element) that generates a large amount of heat can be provided with a cooling mechanism (a heat releasing module or a heat receiving module, which is not illustrated). The board 10 and the electronic components constitute at least a part of a control circuit (not illustrated). The control circuit can comprise an image signal processing circuit, a tuner 10a, a high-definition multimedia interface (HDMI) signal processor, an audio video (AV) input terminal, a remote-control signal receiver, a controller, a selector, an on-screen display interface, a storage module (e.g., a read-only memory (ROM), a random access memory (RAM), and a hard disk drive (HDD)), and a voice signal processing circuit, for example. The control circuit controls output of an image (a moving image, a still image, or the like) by the display screen 6a of the display device 6, output of sound by a speaker (not illustrated), emission of light by a light emitting diode (LED, which is not illustrated), and the like. The display device 6, the speaker, the LED, and the like are examples of an output module.

The housing 2 comprises a component housing 12 that houses a component 11 in a removable manner. In the present embodiment, for example, the component housing 12 is bored in the end 2d illustrated on the right side of FIG. 1 as viewed from the front. The component housing 12 is an example of an opening. Specifically, the component 11 is a stylus, a stylus pen, and a pen, for example. The component housing 12 extends in a direction along the front surface 2a, the rear surface 2b, and the end 2c.

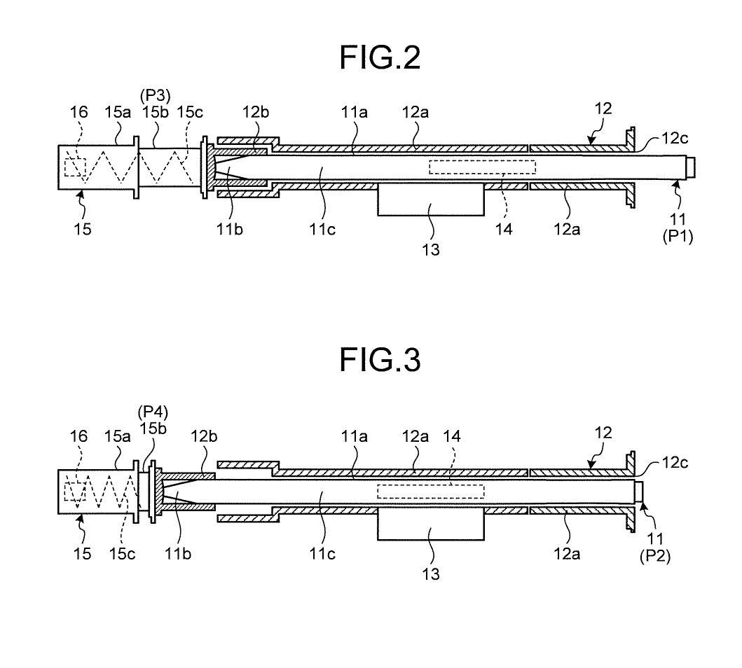

The component housing 12 comprises a wall 12a and a movable supporting portion (a supporting portion) 12b, for example. The wall 12a covers at least a portion of a side surface 11a of the component 11. In other words, the wall 12a can cover the entire circumference of the side surface 11a of the component 11, or can comprise an opening (a slit, a hole, or the like). Furthermore, the wall 12a can be formed of a plurality of members and components. In the present embodiment, the wall 12a functions as a retainer, a supporting portion, a positioning portion, and/or a guide for the component 11. The movable supporting portion 12b supports an end (a tip or a point) 11b of the component 11. Furthermore, the movable supporting portion 12b moves in an entering and leaving direction of the component 11 (horizontal direction in FIGS. 2 and 3) together with the component 11. In other words, the movable supporting portion 12b functions not only as the retainer, the supporting portion, and the guide for the component 11, but also as a moving portion.

Furthermore, in the present embodiment, for example, an electromagnet 13 is provided as an actuator (restraining portion) that restrains the component 11 in the component housing 12 from coming out of the component housing 12. In the present embodiment, for example, the component 11 comprises an axis 11c and a magnetic portion 14. The axis 11c is made of a synthetic resin material, for example. The magnetic portion 14 is made of a metal material and a magnet, for example. The magnetic portion 14 is arranged in the axis 11c, and at least a part of the magnetic portion 14 is embedded in the axis 11c. In the present embodiment, for example, while the magnetic portion 14 is wholly covered with the synthetic resin material forming the axis 11c, at least a part of the magnetic portion 14 can be exposed to the side surface 11a and the end 11b of the axis 11c. Attractive force acts between the electromagnet 13 that generates magnetic force and the magnetic portion 14. Thus, the electromagnet 13 generates the magnetic force to attract the magnetic portion 14, thereby restraining the component 11 from coming out from the component housing 12.

The component housing 12 comprises a pushing device 15. The pushing device 15 comprises a fixing portion 15a, a movable portion 15b, a locking device 16, and a biasing portion 15c, for example. The fixing portion 15a is fixed to the housing 2. The movable portion 15b is supported by the fixing portion 15a in a movable manner. Furthermore, the movable portion 15b can move at least between a third position P3 distant from the fixing portion 15a and a fourth position P4 closer to the fixing portion 15a. The biasing portion 15c biases the movable portion 15b in a direction away from the fixing portion 15a, that is, in a direction from the fourth position P4 (FIG. 3) toward the third position P3 (FIG. 2). The biasing portion 15c is formed as an elastic body, for example, and as a coil spring or the like specifically. The locking device 16 causes the movable portion 15b to remain at the fourth position P4 in a locking state. If the lock performed by the locking device 16 is canceled, the movable portion 15b is pushed by the biasing portion 15c, and moves from the fourth position P4 to the third position P3.

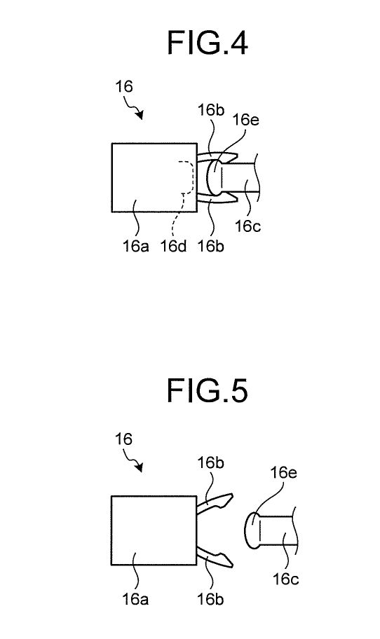

As illustrated in FIGS. 4 and 5, the locking device 16 comprises a body 16a, a first engaging portion 16b, a second engaging portion 16c, and an operating module 16d, for example. The body 16a is fixed to the fixing portion 15a. The first engaging portion 16b is supported by the body 16a in a movable manner. The second engaging portion 16c is fixed to the movable portion 15b. The operating module 16d is supported by the body 16a in a movable manner. In the present embodiment, for example, the first engaging portion 16b provided in plurality (two, in the example of FIGS. 4 and 5) in an arm-shape (a hook-shape) holds and retains a diameter expanded portion (an expanded portion or an uneven portion) 16e provided to a tip of the second engaging portion 16c. The locking device 16 has a push-push mechanism containing a heart cam, for example. Therefore, the locking device 16 can alternately switch a state between a state in which the second engaging portion 16c pushes the operating module 16d to cause the first engaging portion 16b to hold and retain the second engaging portion 16c (as illustrated in FIG. 4) and a state in which the second engaging portion 16c pushes the operating module 16d to cause the first engaging portion 16b to separate from the second engaging portion 16c (as illustrated in FIG. 5). As described above, by the biasing force generated by the biasing portion 15c of the pushing device 15, force acts on the movable portion 15b in the direction away from the fixing portion 15a. Therefore, in the state illustrated in FIG. 5, the component 11 is pushed by the movable portion 15b and the movable supporting portion 12b integrated therewith in a direction coming out from the component housing 12, resulting in the state illustrated in FIG. 2. The position of the component 11 in FIG. 2 is a first position P1. The position of the component 11 in FIG. 3 is a second position P2.

As is clear from FIGS. 2 and 3, in the present embodiment, for example, a length of an overlapping portion between the electromagnet 13 and the magnetic portion 14 are (length in the entering and leaving direction of the component 11) in the state where the component 11 is positioned at the first position P1 (that is, the state where the movable portion 15b is positioned at the third position P3 in FIG. 2) is smaller than a length of the overlapping portion between the electromagnet 13 and the magnetic portion 14 (length in the entering and leaving direction of the component 11) in the state where the component 11 is positioned at the second position P2 (that is, the state where the movable portion 15b is positioned at the fourth position P4 in FIG. 3). As a result, in the state where the movable portion 15b is positioned at the third position P3 closer to an open end 12c of the component housing 12, and where the component 11 is positioned at the first position P1 with a portion thereof protruding from the open end 12c of the component housing 12 as illustrated in FIG. 2, the attractive force between the electromagnet 13 under operation and the magnetic portion 14 becomes weak compared to that in the state where the movable portion 15b is positioned at the fourth position P4 on the back side of the component housing 12, and where the component 11 is positioned at the second position P2 while being housed in the component housing 12 as illustrated in FIG. 3. Therefore, according to the present embodiment, for example, the user can push the component 11 toward inside of the component housing 12 by a finger or the like in a relatively simple manner, thereby allowing the component 11 to be housed in the component housing 12.

Furthermore, in the present embodiment, even in the state illustrated in FIG. 2, that is, even in the state where the attractive force between the electromagnet 13 under operation and the magnetic portion 14 is weaker than that in the state illustrated in FIG. 3, the attractive force between the electromagnet 13 under operation and the magnetic portion 14 is set stronger than the gravity acting on the component 11. Therefore, for example, even if the housing 2 is positioned so that the open end 12c is positioned on the lower side, the component housing 12 is opened vertically downward, and the entering and leaving direction of the component housing 12 is along the vertical direction, the electromagnet 13 operates (generates the magnetic force). As a result, it is possible to restrain the component 11 from coming out from the component housing 12, and moving away from the housing 2 more reliably.

Furthermore, FIG. 2 illustrates the state where the movable portion 15b of the pushing device 15 is positioned at the third position P3, which is a state the component 11 is likely to obtain when the component 11 is not thrust into the component housing 12 but inserted therein with relatively weak force. Therefore, according to the present embodiment, for example, it is possible to restrain the component 11 from coming out from the component housing 12, and moving away from the housing 2 more reliably. As described above, the attractive force between the electromagnet 13 and the magnetic portion 14 is stronger in the state illustrated in FIG. 3 than the state illustrated in FIG. 2. Therefore, according to the present embodiment, even if the component 11 is housed in the component housing 12, for example, the electromagnet 13 operates (generates the magnetic force), thereby making it possible to restrain the component 11 from coming out from the component housing 12, and moving away from the housing 2 more reliably.

It may be understood that, by arranging the electromagnet 13 and the magnetic portion 14 so as to face each other in a direction intersecting the entering and leaving direction of the component 11 with respect to the component housing 12 (a direction orthogonal thereto in the present embodiment, for example), the difference in the magnitude of the attraction between the electromagnet 13 and the magnetic portion 14 depending on the positions of the component 11 in the component housing 12 describe above is realized in a relatively simple manner.

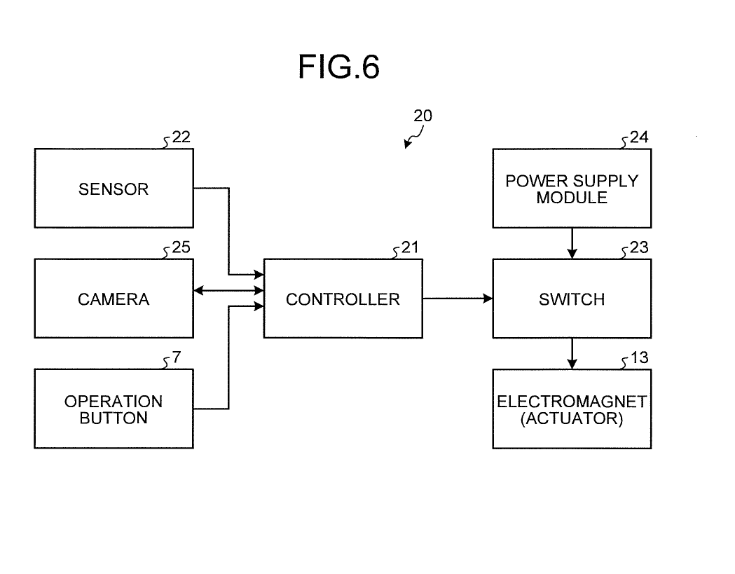

Furthermore, in the present embodiment, the electromagnet 13 operates not always but limitedly, for example. Specifically, for example, the electromagnet 13 generates the magnetic force when the television receiver 1 (housing 2) is subjected to some external force. As a result, for example, if the user lifts or carries the television receiver 1, it is possible to restrain the component 11 from coming out from the component housing 12. In relation to such an operation of the electromagnet 13, the television receiver 1 according to the present embodiment comprises a control circuit 20 illustrated in FIG. 6, for example. Specifically, for example, the control circuit 20 comprises a controller (a determination module or an actuator controller) 21, a sensor 22, and a switch 23. The switch 23 switches so as to electrically connect or disconnect a power supply module (e.g., a battery) 24 and the electromagnet 13 with each other. The sensor 22 can be configured as a gyro sensor, an acceleration sensor, and a vibration sensor, for example. In the control circuit 20, in response to an output of a signal from the sensor 22, that is, if the level of a physical amount indicated by the output signal from the sensor 22 (e.g., output voltage of the sensor 22) is equal to or higher than a predetermined threshold value, for example, the controller 21 turns the switch 230N to supply electric power from the power supply module 24 to the electromagnet 13. In the present embodiment, with such a configuration, if the user lifts or carries the television receiver 1, for example, it is possible to restrain the component 11 from coming out from the component housing 12. The period of time during which the electric power is supplied to the electromagnet 13 may be the period of time during which the output of the signal from the sensor 22 is equal to or higher than the threshold value. Alternatively, the period of time during which the electric power is supplied to the electromagnet 13 may be a predetermined period of time from a point at which the output of the signal from the sensor 22 becomes equal to or higher than the threshold value.

If the television receiver 1 serving as the electronic device is not being used, the controller 21 can cause the electromagnet 13 serving as an actuator to operate. If the television receiver 1 comprises the camera 25, for example, the controller 21 can determine whether the television receiver 1 is being used based on an image captured by the camera 25. If the image thus captured is dark, for example, it can be assumed that nobody is using (watching) the television receiver 1, or that the television receiver 1 is housed in a bag or the like. In such a state, even if the electromagnet 13 is operated to restrain the component 11 from coming out of the component housing 12, the user is not too much affected because the component 11 is not in use. Therefore, in a state where the television receiver 1 is assumed not to be used based on brightness value information or video of the image captured by the camera 25 (e.g., a state where the brightness value is equal to or lower than a predetermined threshold value), for example, the controller 21 can cause the electromagnet 13 to operate, thereby restraining the component 11 from coming out from the component housing 12.

Furthermore, if a section of the television receiver 1 different from the component 11 is being used, the controller 21 can cause the electromagnet 13 serving as the actuator to operate. When the operation buttons 7 is being operated, for example, even if the electromagnet 13 operates to restrain the component 11 from coming out from the component housing 12, the user is not too much affected because the component 11 is not in use. Therefore, in a state where an input signal is output from the operation buttons 7, for example, the controller 21 can cause the electromagnet 13 to operate, thereby restraining the component 11 from coming out from the component housing 12.

Moreover, if the television receiver 1 serving as the electronic device is not in use, or if a section of the television receiver 1 different from the component 11 is in use, the controller 21 can cause the electromagnet 13 serving as the actuator to operate in response to the output of the signal from the sensor 22. In this case, for example, it is possible to make the operation time of the actuator shorter. Therefore, for example, it is possible to reduce wasted power consumption in association with the operation of the actuator.

As described above, in the present embodiment, in response to the output of the signal from the sensor 22 based on external force applied to the housing 2, the electromagnet 13 serving as the actuator restrains the component 11 from coming out from the component housing 12. Therefore, according to the present embodiment, for example, it is possible to further restrain the component 11 housed in a removable manner in the component housing 12 provided to the housing 2 from coming out from the component housing 12. Furthermore, in the present embodiment, the actuator comprises the electromagnet 13 that attracts the magnetic portion 14 provided to the component 11 in response to the output of a signal from the sensor 22. Therefore, according to the present embodiment, for example, it is possible to provide the actuator having a relatively simple configuration.

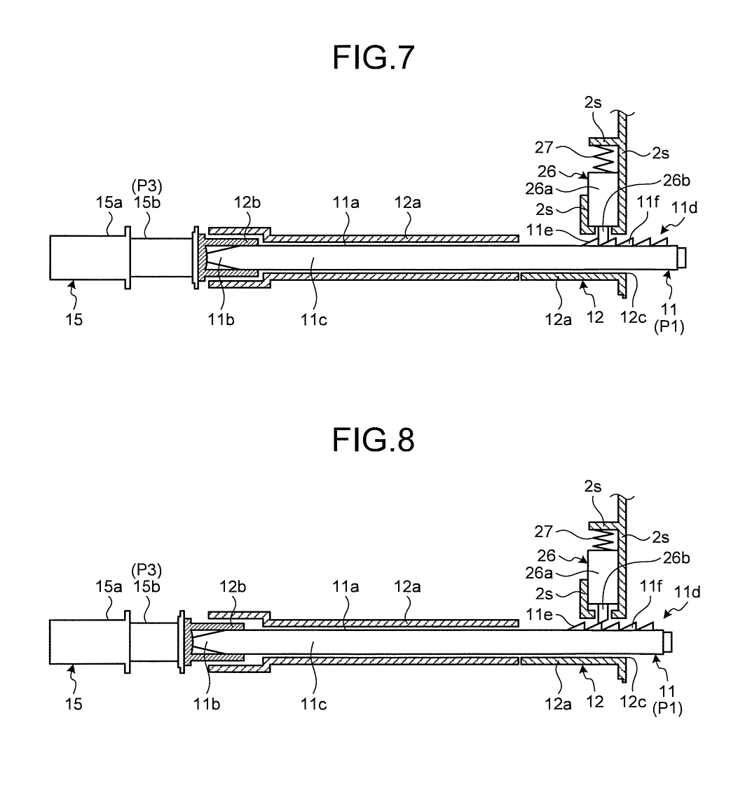

A second embodiment is the same as the first embodiment except that the actuator is not the electromagnet 13 but a solenoid actuator 26. In other words, the solenoid actuator 26 and the configuration illustrated in FIGS. 7 to 10 to which the solenoid actuator 26 is provided in the present embodiment can be realized by being substituted for the configuration corresponding thereto in the first embodiment.

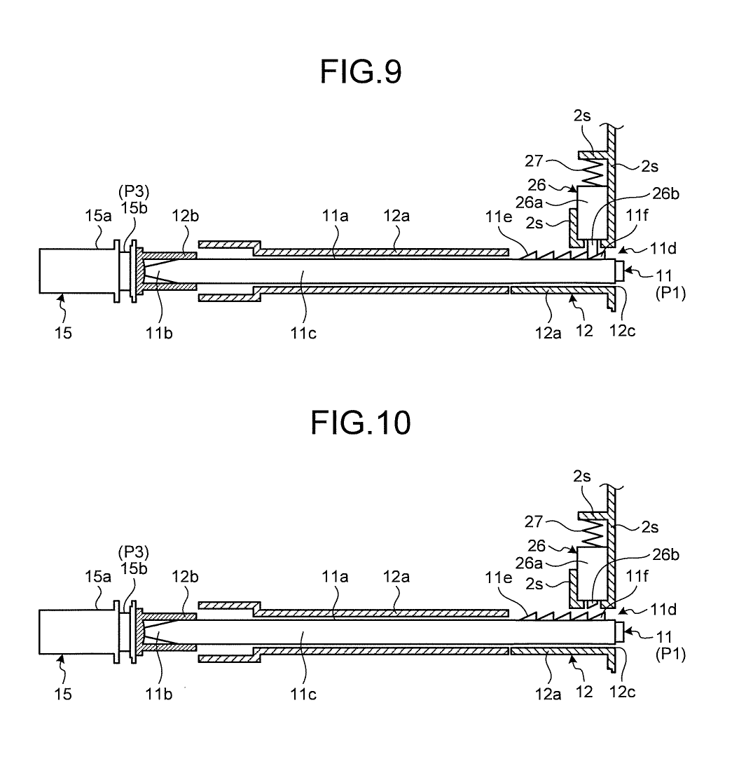

The solenoid actuator 26 comprises a body 26a and a movable portion 26b. The body 26a houses an electromagnet (a solenoid, which is not illustrated) therein. The movable portion 26b is supported by the body 26a in a movable manner. The movable portion 26b can move between a position at which the protruding amount thereof from the body 26a is large (FIGS. 7 to 9) and a position at which the protruding amount thereof from the body 26a is small (FIG. 10). By switching electrical connection and disconnection of the electromagnet, it is possible to switch the movable portion 26b between the position at which the protruding amount thereof is large (at which the movable portion 26b protrudes) and the position at which the protruding amount thereof is small (at which the movable portion 26b is retracted). In the present embodiment, the body 26a is an example of a driver, and the movable portion 26b is an example of an engaging portion. If the component 11 is to be restrained from coming out from the component housing 12 based on output from the sensor 22 or the like, the movable portion 26b protrudes from the body 26a to engage with a latch lid provided to the component 11, as illustrated in FIG. 9. In other words, the position of (a tip of) the movable portion 26b illustrated in FIG. 9 is an example of a position at which the movable portion 26b engages with the component 11. Furthermore, if the component 11 is not to be restrained from coming out from the component housing 12, the movable portion 26b is retracted into the body 26a to a position at which the movable portion 26b is disengaged from the latch lid provided to the component 11 as illustrated in FIG. 10. In other words, the position of (the tip of) the movable portion 26b illustrated in FIG. 10 is an example of a position at which the movable portion 26b is disengaged from the component 11.

Furthermore, in the present embodiment, the solenoid actuator 26 is arranged in a movable manner in a direction intersecting with the moving direction of the component 11 in the component housing 12 (a direction orthogonal thereto in the present embodiment, for example). Specifically, the solenoid actuator 26 is surrounded by a protruding portion (wall) 2s provided to the housing 2, and is supported by the housing 2 in a movable manner in the direction intersecting with the moving direction of the component 11. Furthermore, the solenoid actuator 26 is biased toward the component 11 by a biasing portion 27. The latch (engaging portion, movement restricting portion, or claw portion) 11d that is engaged with the movable portion 26b in the direction along which the component 11 leaves the component housing 12, and that is disengaged from the movable portion 26b in the direction along which the component 11 enters the component housing 12 is provided to the component 11 between the component 11 and the movable portion 26b. The latch lid comprises a plurality of projections (craw portions, or craws) 11f that have an inclined surface 11e extending toward the solenoid actuator 26 in a direction from the inside of the component housing 12 (left side in FIGS. 7 to 10) to the open end 12c side (right side in FIGS. 7 to 10). In such a configuration, even if the component 11 is to be moved in the direction of leaving the component housing 12, the latch lid is engaged with the movable portion 26b, thereby not allowing the component 11 to move out of the component housing 12. By contrast, if the component 11 is to be moved in the direction of entering the component housing 12, the movable portion 26b is pushed by the inclined surface (pushing surface, or pushing portion) lie of the latch 11d, whereby the solenoid actuator 26 moves in the direction away from the component 11 as illustrated in FIG. 8. As a result, the movable portion 26b moves toward the position at which the movable portion 26b is disengaged from the latch lid (that is, in the direction away from the latch 11d). In other words, according to the present embodiment, even if the solenoid actuator 26 restrains the component 11 from coming out from the component housing 12, the component 11 is not restrained from entering into the component housing 12. Therefore, according to the present embodiment, for example, it is possible to avoid the case where the component 11 is fixed by an operation of the actuator (solenoid actuator 26 in the present embodiment), and becomes some kind of obstacle with a part of the component 11 protruding from the component housing 12 as illustrated in FIG. 7. Specifically, it is possible to avoid the case where the component 11 thus protruding interferes with a finger of the user or other objects, for example.

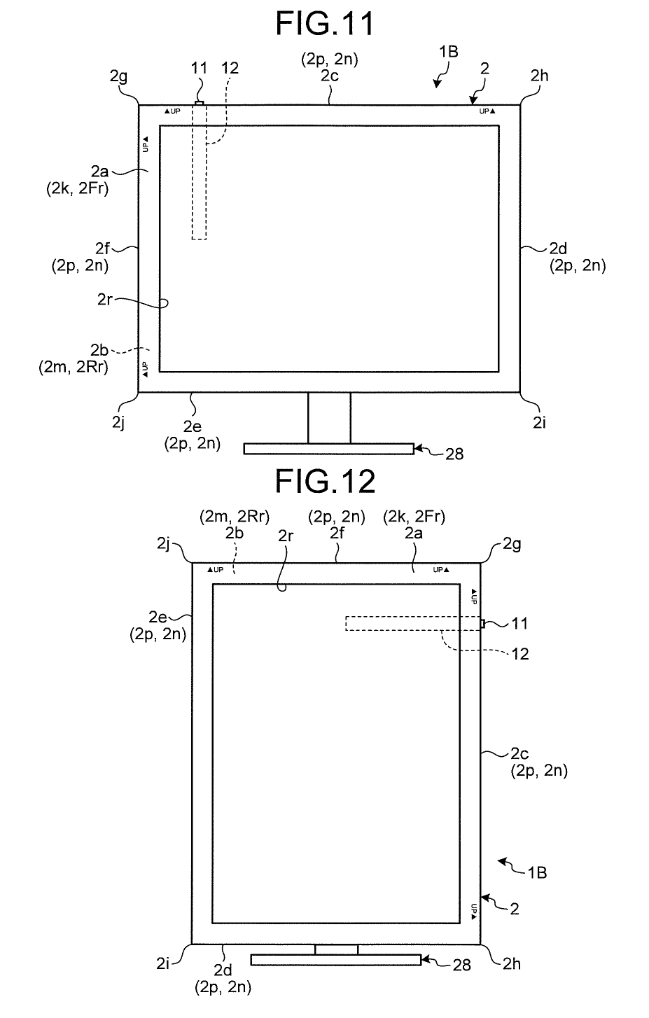

A television receiver 1B, which is an example of the electronic device according to a third embodiment, comprises a supporting portion (a support, a base, or a stand) 28 and the housing 2 as illustrated in FIGS. 11 and 12. The supporting portion 28 is placed on a mounting (not illustrated), such as a desk, a shelf, and a cabinet, and supports the housing 2. The supporting portion 28 may support the housing 2 fixedly, or support the housing 2 in a movable (rotatable or slidable) manner. Rotation aspects of the housing 2 with respect to the supporting portion 28 include a tilt, a swivel, and a pivot. While the specifications of the housing 2 are different from those in the first embodiment in detail in terms of comprising no operation button 7, for example, the basic configuration of the housing 2 is the same as that in the first embodiment. Therefore, detailed explanation of the housing 2 will be omitted.

In the present embodiment, the direction of an image output on the display screen 6a while the television receiver 1B is being used can be changed depending on the position of the housing 2. A control circuit (not illustrated) provided in the housing 2, for example, can change the direction and the size of an image output on the display screen 6a in accordance with a detection result of a sensor (e.g., a gyro sensor and an acceleration sensor, which is not illustrated) provided in the housing 2. Furthermore, the control circuit can restrict the position of the image to some positions. Specifically, for example, when the end 2c of the housing 2 is positioned above the end 2e (a first position illustrated in FIG. 11), the control circuit can display an image whose top is on the end 2c side on the display screen 6a. By contrast, when the end 2f is positioned above the end 2d (a second position illustrated in FIG. 12), the control circuit can display an image whose top is on the end 2f side on the display screen 6a. If the position of the housing 2 is changed from a previous position to the first position or the second position, the control circuit changes the image on the display screen 6a to an image corresponding to the position. By contrast, if the position is changed from the previous position to a position other than the first position or the second position (that is, in this example, a position at which the end 2e is positioned above the end 2c or a position at which the end 2d is positioned above the end 2f), the control circuit does not change the image on the display screen 6a. Such control can restrict the position of the housing 2 (television receiver 1B) being used by the user.

In the present embodiment, the component housing 12 is bored in the end positioned above in the first position or the second position serving as the position being used (end 2c positioned above in the first position in the example of FIGS. 11 and 12). Therefore, according to the present embodiment, for example, it is possible to realize a configuration with which the component 11 is unlikely to move out of the component housing 12 compared with the case where the component housing 12 is bored in the end 2d or 2e positioned below in the first position or the second position.

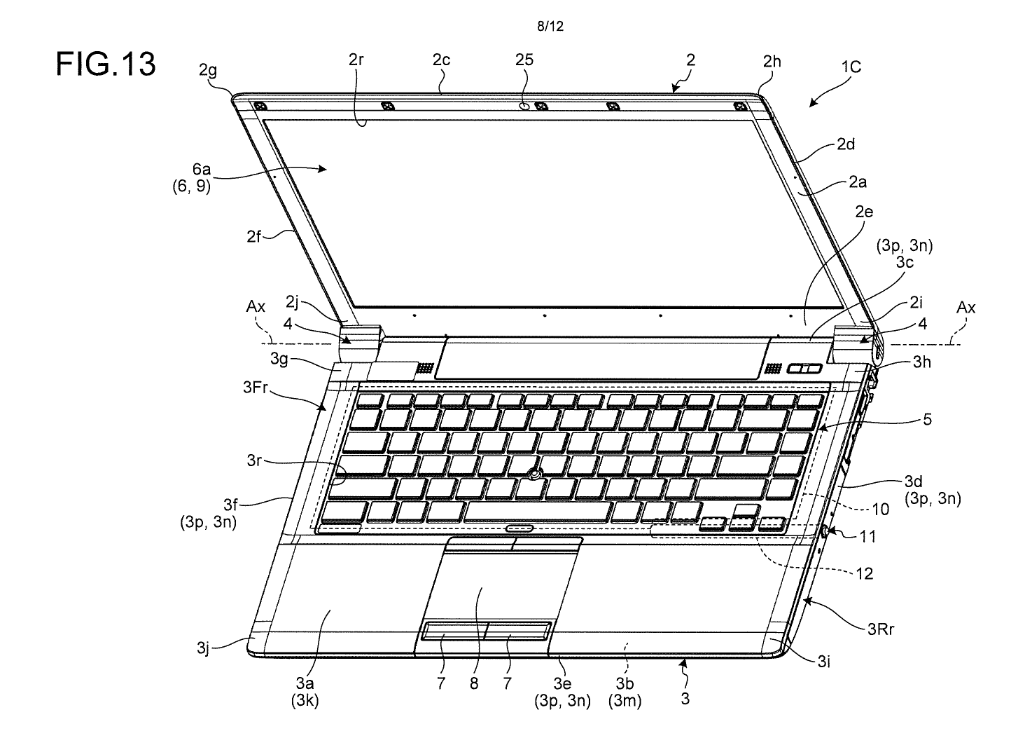

As illustrated in FIG. 13, an electronic device 10 according to a fourth embodiment is configured as a so-called notebook personal computer. The component housing 12 that houses the component 11 disclosed in the first embodiment and the second embodiment can be provided to the electronic device 10. The electronic device 10 comprises the rectangle flat housing (first housing) 2 and a rectangle flat housing (second housing) 3. The housing 2 and the housing 3 are connected to each other via a hinge (a connecting module, a hinge mechanism, or a combining module) 4 in a relatively rotatable manner about a rotation axis Ax, for example, between an unfolded state illustrated in FIG. 13 and a folded state, which is not illustrated.

While the specifications of the housing 2 are different from those in the first embodiment in detail in terms of comprising no operation button 7 and no board 10, for example, the basic configuration of the housing 2 is the same as that of the housing 2 in the first embodiment. Therefore, detailed explanation of the housing 2 will be omitted. By contrast, in the second housing 3, a keyboard 5, the operation buttons 7, a pointing device 8, and the like serving as input receives are provided so as to be exposed on an upper surface 3a serving as an outer surface. In the unfolded state illustrated in FIG. 13, the keyboard 5, the display device 6, the operation buttons 7, the pointing device 8, and the like are exposed to allow the user to use the modules. By contrast, in the folded state (not illustrated), the front surface 2a and the upper surface 3a closely face each other. As a result, the keyboard 5, the display device 6, the operation buttons 7, the pointing device 8, and the like are concealed by the housings 2 and 3.

The housing 3 is configured in a flat rectangular parallelepiped shape that has a small width in the front-back direction. The housing 3 comprises the upper surface (front face, surface, first surface, or first surface portion) 3a, and a lower surface (a back surface, a surface, a second surface, or a second surface portion) 3b opposite thereto. The upper surface 3a and the lower surface 3b are approximately parallel to each other. Furthermore, the housing 3 comprises four ends (sides or edges) 3c to 3f and four corners (peaks, curves, or ends) 3g to 3j in a planer view. The ends 3c and 3e are examples of a long side, and the ends 3d and 3f are examples of a short side.

The housing 3 further comprises a wall (a first wall, a first section, a plate, a frame, a front wall, a face wall, or a top wall) 3k comprising the upper surface 3a and a wall (a second wall, a second section, plate, a rear wall, a back wall, or a bottom wall) 3m comprising the lower surface 3b. The walls 3k and 3m are in a rectangular shape (an oblong shape in the present embodiment, for example). Furthermore, the housing 3 comprises four walls (third walls, third sections, plates, side walls, end walls, standing walls, or extending portions) 3n comprising a side surface (a surface, a surrounding surface, or a third surface) 3p extending between the wall 3k and the wall 3m. The wall 3k comprises an opening 3r in a rectangular shape, for example.

Furthermore, the housing 3 can be configured by combining a plurality of components (divided parts or members). The housing 3, for example, comprises a first member (a first section, a front side member, or a cover) 3Fr containing at least the wall 3k and a second member (a second section, a rear side member, a base, or a bottom) 3Rr containing at least the wall 3m. The wall 3n can be contained in at least one of the first member 3Fr and the second member 3Rr (e.g., the second member 3Rr). The housing 3 can comprise a third member (a third section, a middle member, a dividing member, a barrier member, a wall member, an intervening member, an inner plate, a middle plate, or a middle frame, which is not illustrated) arranged between the first member 3Fr and the second member 3Rr in addition to the first member 3Fr and the second member 3Rr. In this case, the wall 3n can be contained in the third member. The housing 3 can be made of a metal material, a synthetic resin material, and the like.

The housing 3 houses the board (circuit board, control board, or main board) 10 on the lower side (back side, other side, or wall 3m side) of the keyboard 5. The board 10 is arranged in a manner parallel to the keyboard 5. A plurality of electronic components (components or elements, which are not illustrated), such as a CPU, are mounted on the board 10. The electronic components include a heating element. An electronic component (heating element) that generates a large amount of heat can be provided with a cooling mechanism (a heat releasing module or a heat receiving module, which is not illustrated). The board 10 and the electronic components constitute at least a part of a control circuit (not illustrated). The control circuit can comprise a controller and a storage module (e.g., a ROM, a RAM, and an HDD), for example. The control circuit controls output of an image (a moving image, a still image, or the like) by the display screen 6a of the display device 6, output of sound by a speaker (not illustrated), emission of light by an LED (not illustrated), and the like. The display device 6, the speaker, the LED, and the like are examples of an output module.

In the present embodiment, the housing 3 comprises the component housing 12 that houses the component 11 in a removable manner. In the present embodiment, for example, the component housing 12 is bored in the end 3d on the right side in the planer view. The component housing 12 is an example of an opening. Specifically, the component 11 is a stylus, a stylus pen, and a pen, for example. The component housing 12 extends in a direction along the upper surface 3a, the lower surface 3b, and the end 3c. Because the configuration of the component housing 12 is the same as those in the first embodiment and the second embodiment, explanation thereof will be omitted.

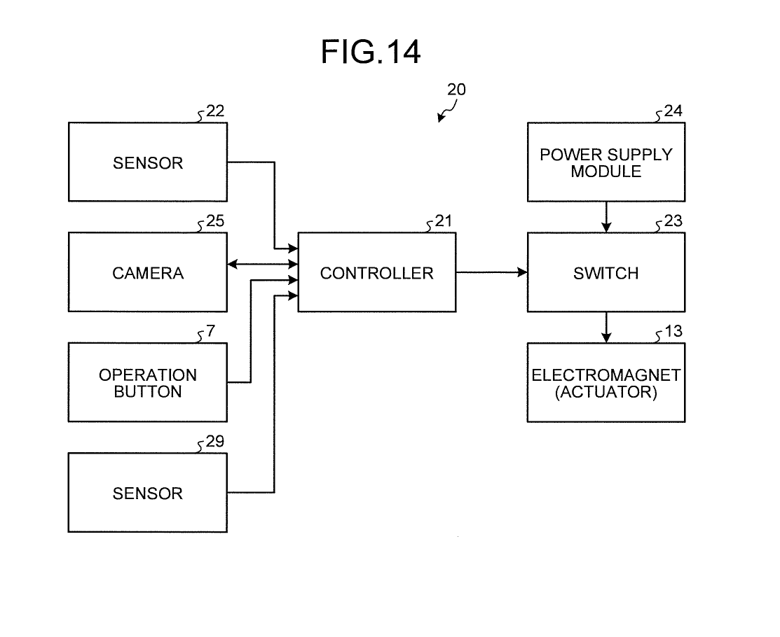

In the present embodiment as well, the electromagnet 13 serving as an actuator (not illustrated in FIG. 13, and refer to FIG. 14) generates magnetic force when the electronic device 1C (housing 3) is subjected to some external force. As a result, for example, if the user lifts or carries the electronic device 1C, it is possible to restrain the component 11 from coming out from the component housing 12. In relation to such an operation of the electromagnet 13, the electronic device 1C according to the present embodiment comprises the control circuit 20 illustrated in FIG. 14, for example. Specifically, for example, the control circuit 20 comprises the controller (determination module or actuator controller) 21, the sensor 22, and the switch 23. The switch 23 switches electrical connection and disconnection between the power supply module (e.g., a battery) 24 and the electromagnet 13. The sensor 22 can be configured as a gyro sensor, an acceleration sensor, and a vibration sensor, for example. In the control circuit 20, depending on output of a signal from the sensor 22, that is, if the level of a physical amount indicated by the output signal from the sensor 22 (e.g., output voltage of the sensor 22) is equal to or higher than a predetermined threshold value, for example, the controller 21 turns the switch 230N to supply electric power from the power supply module 24 to the electromagnet 13. In the present embodiment, with such a configuration, if the user lifts or carries the electronic device 10, for example, it is possible to restrain the component 11 from coming out from the component housing 12. The period of time during which the electric power is supplied to the electromagnet 13 may be the period of time during which the output of the signal from the sensor 22 is equal to or higher than the threshold value. Alternatively, the period of time during which the electric power is supplied to the electromagnet 13 may be a predetermined period of time from a point at which the output of the signal from the sensor 22 becomes equal to or higher than the threshold value.

In the present embodiment as well, if the electronic device 10 is assumed not in use based on brightness value information or video of the image captured by the camera 25 (e.g., a state where the brightness value is equal to or lower than a predetermined threshold value), for example, the controller 21 can cause the electromagnet 13 to operate, thereby restraining the component 11 from coming out from the component housing 12. Furthermore, in the present embodiment, if the housing 2 and the housing 3 are close to each other, the electronic device 10 is assumed not to be being used. Therefore, if the electronic device 1C is assumed not in use based on a signal output from a sensor (an opening and closing sensor, a close sensor, a distance sensor, or a magnetic sensor) 29 indicating that the housing 2 and the housing 3 are close to each other (e.g., a state where a signal corresponding to the state where the distance between the housing 2 and the housing 3 becomes equal to or smaller than a predetermined value is output), it is possible to cause the electromagnet 13 to operate, thereby restraining the component 11 from coming out from the component housing 12. Furthermore, in the present embodiment as well, if an input signal is output from the keyboard 5, the operation button 7, and the pointing device 8, for example, the controller 21 can cause the electromagnet 13 to operate, thereby restraining the component 11 from coming out from the component housing 12.

Moreover, in the present embodiment as well, if the electronic device 1C is not in use, or if a section of the electronic device 1C different from the component 11 is in use, the controller 21 can cause the electromagnet 13 serving as the actuator to operate in response to the output of the signal from the sensor 22. In this case, for example, it is possible to make the operation time of the actuator shorter. Therefore, for example, it is possible to reduce wasted power consumption in association with the operation of the actuator. According to the present embodiment, the same advantageous effects as those in the first to the third embodiments can be achieved as well. The solenoid actuator 26 described in the second embodiment may be provided instead of the electromagnet 13.

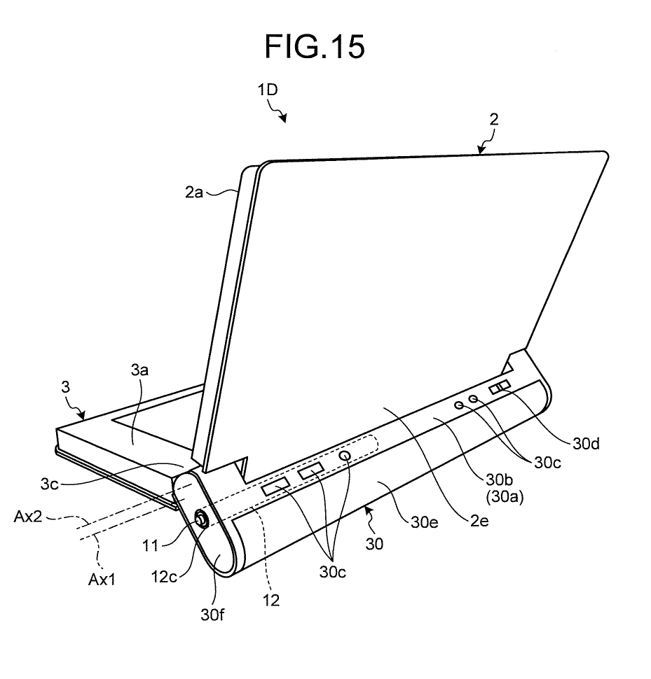

As illustrated in FIG. 15, an electronic device 1D according to a fifth embodiment is configured as a so-called notebook personal computer. The electronic device 1D comprises the rectangle flat housing (first housing) 2 and the rectangle flat housing (second housing) 3. The housing 2 and the housing 3 are connected to each other via a connecting section 30 in a relatively rotatable manner (relatively movable manner) between an unfolded state illustrated in FIG. 15 and a folded state, which is not illustrated. In the unfolded state where the housing 2 and the housing 3 are unfolded at the maximum angle (180 degrees), the front surface 2a of the housing 2 and the upper surface 3a of the housing 3 are connected in a nearly plane shape. By contrast, in the folded state, the front surface 2a of the housing 2 and the upper surface 3a of the housing 3 closely face each other.

The connecting section 30 is connected to base ends of the housing 2 and the housing 3, that is, to both the end 2e and the end 3c in a rotatable manner. Specifically, the connecting section 30 and the housing 2 are connected via a first rotation axis Ax1 in a relatively rotatable manner. Furthermore, the connecting section 30 and the housing 3 are connected via a second rotation axis Ax2 in a relatively rotatable manner. The first rotation axis Ax1 and the second rotation axis Ax2 extend along each other, and extend side by side with (in a manner parallel to) each other. A housing 30a of the connecting section 30 houses the hinge (connecting module, hinge mechanism, or combining module) 4. In other words, the housing 30a is an example of a cover for the hinge 4.

In the present embodiment, the connecting section 30 extends not only along the end (side) 2e of the housing 2 and the end (side) 3c of the housing 3, but also in a direction away from the ends 2e and 3c. Furthermore, an outer surface 30b of the connecting section 30 can be provided with connection modules 30c for connecting components such as a connection connector for a digital interface including a connector to which an external connector is inserted (e.g., a connector for an alternating current (AC) adapter, a universal serial bus (USB) connector, and a card connector), and an operation module (an input operation module) 30d, such as an operation button (a push button) and a switch. The connection module 30c is an example of a connection connector. Furthermore, the connecting section 30 can be provided with (hold, house, or be equipped with) a battery 30e that is a power supply for causing the electronic device 1D to operate. The battery 30e can be configured in a detachable manner in the connecting section 30. In the present embodiment, because the connecting section 30 extends along the ends 2e and 3c, the battery 30e that is relatively long and has a larger capacity can be provided thereto.

In the present embodiment, the connecting section 30 comprises the component housing 12 that houses the component 11. The component housing 12 is bored on a surface (a side surface or an end surface) 30f of the connecting section 30, and extends along the longitudinal direction of the ends 2e and 3c, and of the connecting section 30. Thus, the component housing 12 can be provided to the housing 30a of the connecting section 30 connected to both the housing 2 and the housing 3 in a rotatable manner.

An electronic device 1E according to a sixth embodiment is, for example, a personal computer, a television receiver, a smartphone, a smartbook, a mobile phone, and a PDA of a so-called slate-type and a tablet-type comprising a display device having a function of a soft keyboard.

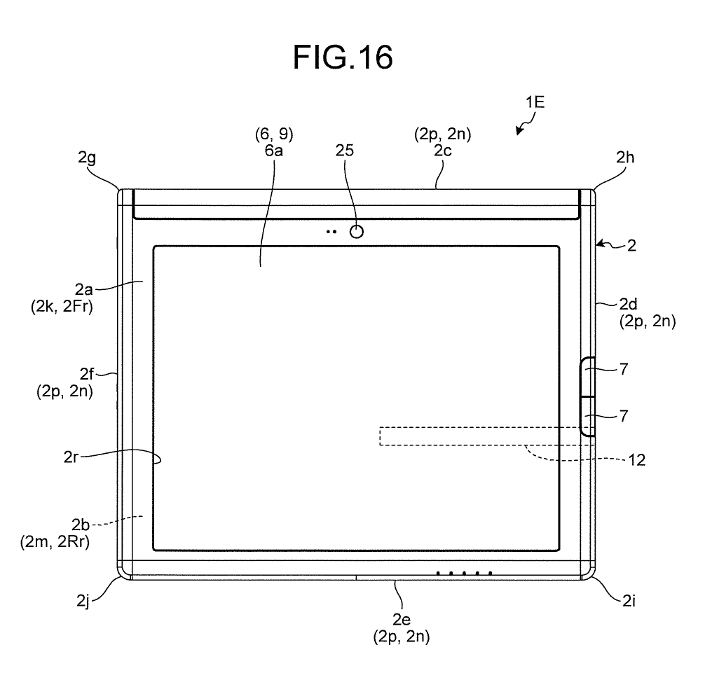

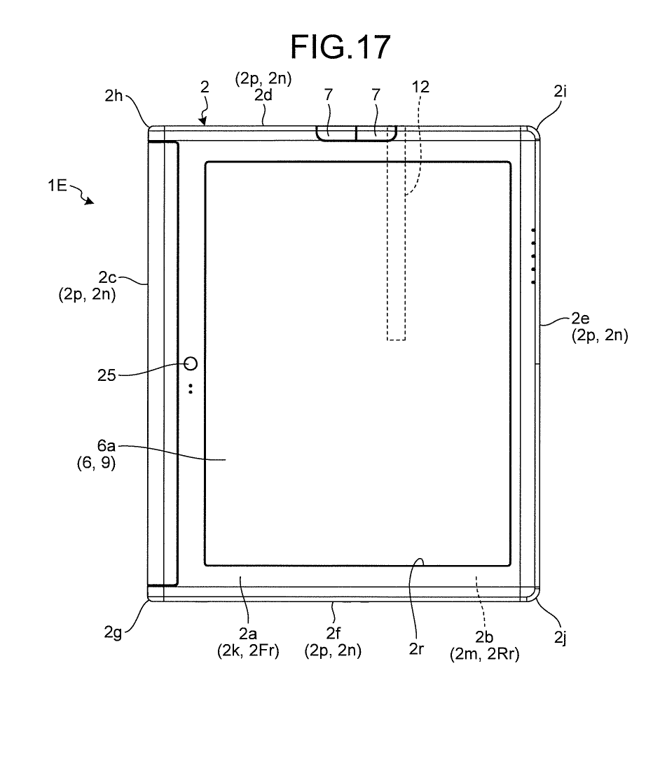

As illustrated in FIGS. 16 and 17, the housing 2 of the electronic device 1E is configured in a rectangular shape (an oblong shape in the present embodiment, for example) viewed from the front and the back. Furthermore, the housing 2 is configured in a flat rectangular parallelepiped shape that has a small width in the front-back direction. The housing 2 comprises the front surface (front face, surface, first surface, or first surface portion) 2a, and the rear surface (back surface, surface, second surface, or second surface portion) 2b opposite thereto. The front surface 2a and the rear surface 2b are approximately parallel to each other. Furthermore, the housing 2 comprises the four ends (sides or edges) 2c to 2f and the four corners (peaks, curves, or ends) 2g to 2j viewed from the front. The ends 2c and 2e are examples of a long side, and the ends 2d and 2f are examples of a short side.

The housing 2 further comprises the wall (first wall, first section, plate, frame, front wall, face wall, or top wall) 2k comprising the front surface 2a and the wall (second wall, second section, plate, rear wall, back wall, or bottom wall) 2m comprising the rear surface 2b. The walls 2k and 2m are in a rectangular shape (an oblong shape in the present embodiment, for example). Furthermore, the housing 2 comprises the four walls (third walls, third sections, plates, side walls, end walls, standing walls, or extending portions) 2n comprising the side surface (surface, surrounding surface, or third surface) 2p extending between the wall 2k and the wall 2m. The wall 2k comprises the opening 2r in a rectangular shape, for example.

Furthermore, the housing 2 can be configured by combining a plurality of components (divided parts). The housing 2, for example, comprises the first member (first section, front side member, or cover) 2Fr containing at least the wall 2k and the second member (second section, rear side member, base, or bottom) 2Rr containing at least the wall 2m. The wall 2n can be contained in at least one of the first member 2Fr and the second member 2Rr (e.g., the second member 2Rr). The housing 2 can comprise the third member (third section, middle member, dividing member, barrier member, wall member, intervening member, inner plate, middle plate, or middle frame, which is not illustrated) arranged between the first member 2Fr and the second member 2Rr in addition to the first member 2Fr and the second member 2Rr. A part of the wall 2n can be contained in the third member. The housing 2 can be made of a metal material, a synthetic resin material, and the like. The second member 2Rr and the third member can be made of a metal material such as magnesium alloy, for example. The first member 2Fr can be made of a synthetic resin material that has lower stiffness than that of the second member 2Rr and the third member, for example. The first member 2Fr, the second member 2Rr, and the third member can comprise a wall (a protruding portion or a protruding wall) such as a rib. The wall increases the stiffness of the housing 2. Furthermore, the third member can be provided with an opening such as a through hole. The opening can make the housing 2 lighter.

In the present embodiment, the direction of an image output on the display screen 6a while the electronic device 1E is being used can be changed depending on the position of the housing 2 (electronic device 1E). A control circuit (not illustrated) provided in the housing 2, for example, can change the direction and the size of an image output on the display screen 6a in accordance with a detection result of a sensor (e.g., a gyro sensor and an acceleration sensor) provided in the housing 2. Furthermore, the control circuit can restrict the position of the image to some positions. Specifically, for example, when the end 2c of the housing 2 is positioned above the end 2e (a first position), the control circuit can display an image whose top is on the end 2c side on the display screen 6a. By contrast, when the end 2d is positioned above the end 2f (a second position), the control circuit can display an image whose top is on the end 2d side on the display screen 6a. If the position of the housing 2 is changed from a previous position to the first position or the second position, the control circuit changes the image on the display screen 6a to an image corresponding to the position. By contrast, if the position is changed from the previous position to a position other than the first position or the second position (that is, in this example, a position at which the end 2e is positioned above the end 2c or a position at which the end 2f is positioned above the end 2d), the control circuit does not change the image on the display screen 6a. Such control can restrict the position of the electronic device 1E being used by the user.

The housing 2 comprises the component housing 12 that houses the component 11 in a removable manner. In the present embodiment, for example, the component housing 12 is bored in the end 2d. The open end 12c is provided to the end 2d that is located on the upper side in any of the used positions (the second position in the example described above), and that is not located on the lower side in a non-used position. Such a configuration causes the open end 12c to be located on the upper side in the used position. Therefore, for example, it is possible to prevent the component 11 from falling off the component housing 12 by the action of gravity. Specifically, the component 11 is a stylus, a stylus pen, and a pen, for example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. The component is not limited to a stylus, a stylus pen, and a pen. Furthermore, various types of actuators can be employed for the actuator. Moreover, specifications (a structure, a type, a direction, a shape, a size, a length, a width, a thickness, a height, the number, an arrangement, a position, a material, and the like) of each of the components can be changed appropriately.

Moreover, the various modules of the systems described herein can be implemented as software applications, hardware and/or software modules, or components on one or more computers, such as servers. While the various modules are illustrated separately, they may share some or all of the same underlying logic or code.

1. An electronic device comprising:
a display device;
a housing comprising an opening, and configured to house the display device;
a component configured to be removably housed in the opening with at least a portion thereof being exposed to outside of the housing;
a sensor configured to output a signal based on external force applied to the housing; and
a restraining portion configured to restrain the component from coming out from the opening, in response to an output of the signal from the sensor.

2. The electronic device of claim 8, wherein the restraining portion comprises an electromagnet configured to attracts a magnetic portion provided to the component in response to the output of the signal from the sensor.

3. The electronic device of claim 2, wherein attractive force acting between the electromagnet and the magnetic portion in a first position of the component at which a portion of the component protrudes from the opening is weaker than attractive force between the electromagnet and the magnetic portion in a second position of the component at which the component is housed in the opening.

4. The electronic device of claim 2, wherein the attractive force acting between the electromagnet and the magnetic portion in the first position of the component at which a portion of the component protrudes from the opening is stronger than gravity acting on the component.

5. The electronic device of claim 2, wherein the electromagnet and the magnetized portion are configured to face each other in a direction intersecting an entering and leaving direction of the component with respect to the opening.

6. The electronic device of claim 2, further comprising:
a pushing device comprising:
a movable portion configured to be movable at least between a third position at which the movable portion comes into contact with the component positioned at the first position and a fourth position at which the movable portion comes into contact with the component positioned at the second position; and
a biasing portion configured to bias the movable portion in a direction from the fourth position toward the third position, wherein
attractive force restraining the component from coming out of the opening acts between the electromagnet and the magnetized portion in a state where the component comes into contact with the movable portion positioned at the third position.

7. The electronic device of claim 8, wherein the restraining portion comprises:
an engaging portion configured to be movable between a position where the engaging portion is engaged with the component and another position where the engaging portion is disengaged from the component; and
a driver configured to move the engaging portion from the position where the engaging portion is disengaged from the component to the position where the engaging portion is engaged with the component in response to the output signal from the sensor, wherein
the engaging portion positioned at the position where the engaging portion is engaged with the component is engaged with the component moving in a direction of leaving the opening, and is pushed by the component moving in a direction of entering into the opening so as to move to the position where the engaging portion is disengaged from the component.

8. An electronic device comprising:
a housing comprising an opening;
a component configured to be removably housed in the opening;
a sensor configured to output a signal based on external force applied to the housing; and
a restraining portion configured to restrain the component from coming out from the opening, in response to an output of the signal from the sensor.

9. An electronic device comprising:
a housing comprising an opening;
a component configured to be removably housed in the opening;
a restraining portion configured to be capable of restraining the component from coming out from the opening; and
a controller configured to control the restraining portion, wherein,
if the electronic device is not being used, the controller is configured to control the restraining portion to restrain the component from coming out from the opening, and,
if a portion of the electronic device different from the component is being used, the controller is configured to control the restraining portion to restrain the component from coming out from the opening.

10. (canceled)
